(19) United States
(12) Patent Application Publication
(10) Pub. No.: US 2011/0149368 A1
(43) Pub. Date: Jun. 23, 2011

(54) PHOTOMIXER MODULE AND TERAHERTZ WAVE GENERATION METHOD THEREOF

(75) Inventors: Namje KIM, Daejeon (KR); Kyung Hyun Park, Daejeon (KR); Young Ahn Leem, Daejeon (KR); Sang-Pil Han, Daejeon (KR); Chul-Wook Lee, Daejeon (KR); Eundeok Sim, Daejeon (KR); Jaeheon Shin, Daejeon (KR)

(73) Assignee: ELECTRONICS AND TELECOMMUNICATIONS RESEARCH INSTITUTE, Daejeon (KR)

(21) Appl. No.: 12/788,244

(22) Filed: May 26, 2010

(30) Foreign Application Priority Data
Dec. 17, 2009 (KR) 10-2009-0126196

(51) Int. Cl. G02F 1/015; H01S 5/50

(52) U.S. Cl. 359/276; 359/344

(57) ABSTRACT

Provided are a photomixer module and a method of generating a terahertz wave. The photomixer module includes a semiconductor optical amplifier amplifying incident laser light and a photomixer that is excited by the amplified laser light to generate a continuous terahertz wave. The photomixer is formed as a single module together with the semiconductor optical amplifier.

### CROSS-REFERENCE TO RELATED APPLICATIONS

This U.S. non-provisional patent application claims priority under 35 U.S.C. §119 of Korean Patent Application No. 10-2009-0126196, filed on Dec. 17, 2009, the entire contents of which are hereby incorporated by reference.

### BACKGROUND OF THE INVENTION

The present invention disclosed herein relates to a semiconductor device, and more particularly, a photomixer module generating a terahertz wave and a method of generating the terahertz wave using the photomixer.

A terahertz wave (THz Wave) is an electromagnetic wave between a microwave and an infrared wave. The terahertz wave is defined within a range from about 0.1 THz to about 10 THz. In view of a spectrum location, the terahertz wave has not only a dielectric transmission property of a radio wave but also a straightness property of a light wave. The terahertz wave that is easily absorbed in moisture may be applied to new technologies such as image, spectrum, and communication fields. In addition, the terahertz wave may be used to see through objects, analyze a bio mechanism having a molecular motion energy level, and analyze a space signal. Furthermore, the terahertz is better than a microwave and a milliliter wave in enabling a superhigh speed local area radio network.

The terahertz wave technology that can be applied to a variety of fields as described above has been limited in its use due to the difficulties in developing a light source and a detector. However, with the development of the semiconductor and laser technologies, a variety of light sources have been recently developed. A photoconductive antenna technology and an optical rectification technology have been well known as the light source for generating the terahertz wave. In addition, a photomixer technology, a hot-hole laser technology, a free electron laser technology, a quantum cascade laser technology, and the like have been developed as continuous-wave technologies for generating the terahertz wave.

Among the technologies, the photomixer technology is regarded as a practically usable technology as compared with other technologies. That is, since a photomixer can be driven at a high temperature, freely vary a frequency, and be realized in a small size system, the photomixer technology is more practicable than other technologies. However, since the photomixer has an output lower than tens of microwatts (μW), which is significantly, lower than that of other terahertz wave generation technologies. The reasons of the lower output of the photomixer may be classified into two reasons according to the terahertz wave generation mechanism,

First, a lower conversion efficiency of a photo current with respect to an incident laser light is the first reason. This reason relates to a transit time of a carrier in the optical conductor and a carrier lifetime. Second, a lower total efficiency in the course of radiating the photo current as the terahertz wave through an antennal is the second reason. This reason can be solved by properly designing a structure of the antennal. Particularly, researches relating to the antenna design have been focused on the improvement of mismatch efficiency. Since the conductivity of the conductor is lowered in a terahertz band, the radiation efficiency should be also considered in the terahertz band.

A Femto second pulse laser is usually used to generate a pulse terahertz wave. Since the Femto second pulse laser has high light intensity, it can generate the pulse terahertz wave having relatively high intensity in a wide frequency band.

In order to a continuous terahertz wave, laser lights having different wavelengths are beaten to be used as excited light. In this case, the intensity of the excited light is lower than that the case where the Femto second laser is used and thus the intensity of the terahertz is relatively weak. Therefore, a high detection rate is inevitably required when the terahertz wave is detected.

In order to generate a continuous terahertz wave that can vary the frequency, two continuous waves output from two distributed feedback lasers (DFBs) or a continuous light source laser is used. When one or both of wavelengths of the continuous waves are varied, the frequency of the signal that is being beaten is varied and thus the terahertz wave generated is varied. At this point, the intensity of the excited light output should be highly maintained while the wavelength is varied.

In recent years, the demands for portable terahertz generating/detecting devices have been getting increased. However, the Femto second laser generating device is being still used as a light source for the excited light used in the terahertz wave generating/detecting device. Accordingly, there is an urgent need for developing a technology for making a terahertz wave generating/detecting device that is small and inexpensive.

### SUMMARY OF THE INVENTION

The present invention provides a photomixer technology for realizing a terahertz wave generator that is small and can be integrated. The present invention also provides a technology that can increase intensity of excited light for generating a terahertz wave and enhance stability of a photomixer.

Embodiments of the present invention provide photomixer modules including: a semiconductor optical amplifier amplifying incident laser light; and a photomixer that is formed as a single module together with the semiconductor optical amplifier and excited by the amplified laser light to generate a continuous terahertz wave.

In other embodiments of the present invention, methods of generating a terahertz wave include generating excited light by beating laser lights having different wavelengths; amplifying the excited light using a semiconductor optical amplifier; and generating the terahertz wave by allowing the amplified excited light to be incident on the photomixer, wherein the semiconductor optical amplifier and the photomixer are formed as a single module.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a photomixer module of an exemplary embodiment;

FIG. 2 is a cross-sectional view taken along line A-A′ of FIG. 1;

FIG. 3 is a schematic view illustrating a method for generating a continuous terahertz wave using the photomixer module of FIG. 1 according to an embodiment;

FIG. 4 is a schematic view illustrating a method for generating a modulated terahertz wave using the photomixer module of FIG. 1 according to an embodiment;

FIG. 5 is a view of a photomixer module according to another embodiment;

FIG. 6 is a view of a terahertz wave generator having the photomixer module of FIG. 1 or 5 according to an embodiment;

FIG. 7 is a view of a terahertz wave generator having the photomixer module of FIG. 1 or 5 according to another embodiment; and

FIG. 8 is a view of a terahertz wave generator having the photomixer module of FIG. 1 or 5 according to another embodiment.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout. Hereinafter, it will be described about an exemplary embodiment of the present invention in conjunction with the accompanying drawings.

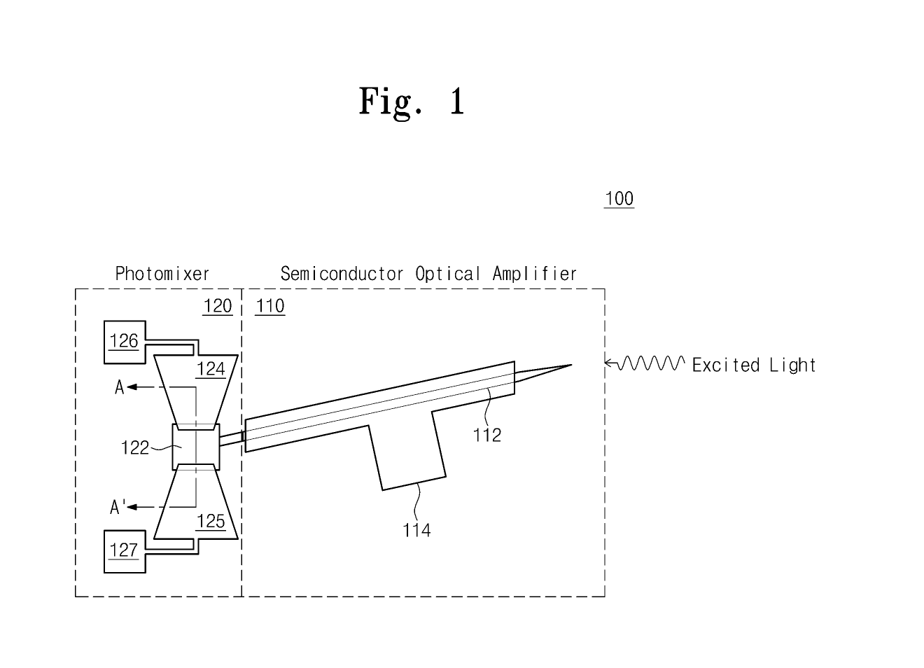

FIG. 1 is an optical amplifier integration type photomixer module of an exemplary embodiment. Referring to FIG. 1, a photomixer module for generating a terahertz wave includes a semiconductor optical amplifier 110 and a photomixer 120.

The semiconductor optical amplifier 110 amplifies incident excited light. The excited light incident on the semiconductor optical amplifier 110 may be provided as a beating signal for generating a continuous terahertz wave. The beating signal is generated by two beating laser lights (beats) having different wavelengths. The frequency of the beating signal corresponds to a difference between the wavelengths of the two laser lights.

However, when beating the semiconductor-based laser lights, intensity of the excited light may be weak. Since the excited light whose intensity is weak or weakened is directly incident on the photomixer 120, intensity of the terahertz generated is also weak. The terahertz wave radiated from the photomixer 120 by the weak excited light requires high detection efficiency during the detection.

Accordingly, the semiconductor optical amplifier 110 for amplifying the excited light is integrated on the photomixer module 100. The semiconductor optical amplifier 110 includes a gain waveguide 112 and an electrode 114 to amplify the incident excited light. The weak excited light incident on the gain waveguide 112 is amplified by a gain current Ig provided through the electrode 114. The amplified excited light will be incident on the photomixer 120.

The semiconductor optical amplifier 110 may include a semiconductor substrate and a waveguide layer for forming the gain waveguide 112. A clad layer is formed on the waveguide layer. The electrode 114 is formed on the clad layer. The gain current Ig is supplied through the electrode 114. In addition, the semiconductor optical amplifier 110 may further include a passive waveguide for transferring the excited light to the gain waveguide 112. The semiconductor optical amplifier 110 amplifies the weak excited light to generate the terahertz wave having the sufficient intensity. The amplified excited light is transferred to the photomixer 120.

Further, the terahertz wave may be modulated by the semiconductor optical amplifier 110. That is, in order to enhancing receive sensitivity when detecting the terahertz wave or to use the terahertz wave for the purpose of the local area communication, there is a need to modulate the terahertz wave. At this point, the terahertz wave may be modulated by the semiconductor optical amplifier 110.

At this point, a bias voltage applied to the photomixer 120 may be fixed. In this state, the gain of the semiconductor optical amplifier 110 is modulated to modulate the terahertz wave. It is advantageous as the saturation output power of the semiconductor optical amplifier 110 integrated on the photomixer module 100 is higher.

The excited light is generated by beating the laser lights having different wavelengths. In this case, the output intensity of each of the laser lights may be 10 mW or more. Accordingly, the saturation output power of the semiconductor optical amplifier 110 may be 20 mW or more for each wavelength considering the coupling efficiency of an output terminal. Therefore, the semiconductor optical amplifier 110 integrated may have at least 16 dBm. Accordingly, the overlap between the excited light that is amplified to have high saturation output power and an active region of the semiconductor optical amplifier 110 is reduced and thus the confinement factor can be reduced. For example, a semiconductor quantum dot optical amplifier, which is known as having the saturation output power of 20 dBm or more, may be used as the semiconductor optical amplifier 110. Alternatively, a taper type optical amplifier having an increased gain region may be used as the semiconductor amplifier 110.

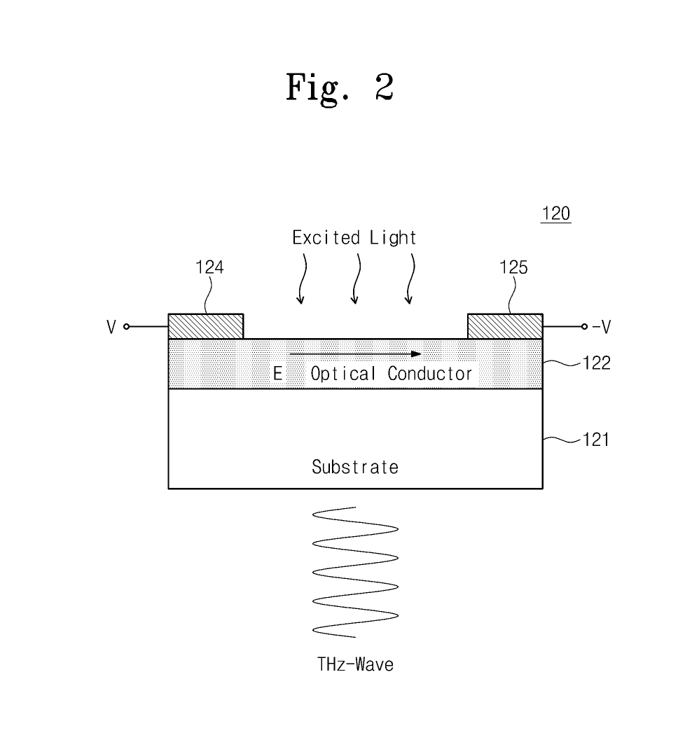

The photomixer 120 may include a substrate, one of an optical conductor 122 and a photodiode that is designed to have a high response speed, which is formed on a substrate, antennas 124 and 125 facing each other on one of the optical conductor 122 and the photodiode. The photomixer 120 may further include electrodes for providing bias for the antennas. However, the present invention is not limited to this. A variety of antennas that are designed in different forms may be used for the photomixer 120. The detailed structure of the photomixer 120 will be described with reference to FIG. 2 that is a cross-sectional view taken along line A-A′ of FIG. 1.

The above-described semiconductor optical amplification integration type photomixer module 100 amplifies the weak excited light that is formed by two mixed lights having different wavelengths and uses the amplified excited light as the excited light for generating the terahertz wave. In addition, in order to generate the stable terahertz wave, the photomixer module 100 adjusts the gain current of the semiconductor optical amplifier 110 or modulates the semiconductor laser that is a light source in a state where the bias applied to the antennas is fixed, thereby modulating the terahertz wave generated.

In the above description, the semiconductor optical amplifier 110 formed on the optical waveguide and the photomixer 120 formed in the waveguide type are integrated with each other to form the photomixer module 100. However, the present invention is not limited to this. For example, the semiconductor optical amplifier 110 and the photomixer 120 may be separately prepared as chips or devices, after which the semiconductor optical amplifier 110 and the photomixer 120 may be assembled as a signal module through a package process. In this case, the focal point of the amplified excited light output from the semiconductor optical amplifier 110 may be focused on the optical conductor 122 of the photomixer 120 using a ball lens and the like.

FIG. 2 is a cross-sectional view taken along line A-A′ of FIG. 1. Referring to FIG. 2, the photomixer 120 may be manufactured by forming the optical conductor 122 or the high response speed photodiode on the substrate and forming the antennas 124 and 125 facing each other on the optical conductor 122 or the high response speed photodiode.

The excited light is a beating signal that is amplified or modulated by the optical amplifier 110. An electric field E is formed on the optical conductor 122 by bias voltage (V, −V) applied to the antennas 124 and 125. When the excited light is incident in this bias state, carriers (electron-hole pairs) are generated in the optical conductor 122 by the light absorption. The carriers are accelerated by the electric field E formed on the optical conductor 122 and momentarily move to the antennas 124 and 125. The antennas 124 and 125 generate the terahertz wave by optical current flowing for a lifespan (hundreds of Femto seconds) of the carriers.

In the photomixer 120 of this embodiment, direct bias voltage (V, −V) may be applied to the antennas 124 and 125. Accordingly, there is no need to bias the antennas 124 and 125 with alternating high voltage for the increase of the terahertz signal detection efficiency and for the modulation for the signal transmission. The voltage applied to the antennas 124 and 125 is as high as tens of volts). Therefore, if the bias voltage applied to the antennas 124 and 125 is modulated with a high frequency, the stability may be significantly deteriorated since a gap between the antennas 124 and 125 is just several micrometers μm. According to this embodiment, this limitation may be solved by enhancing the intensity of the excited light or amplifying/modulating the excited light using the semiconductor optical amplifier 110 in a state where the bias applied to the antennas 124 and 125 is fixed.

The semiconductor optical amplifier integration type photomixer module 100 of this embodiment can satisfy the requirements on the high intensity excited light and the stable terahertz wave modulation condition.

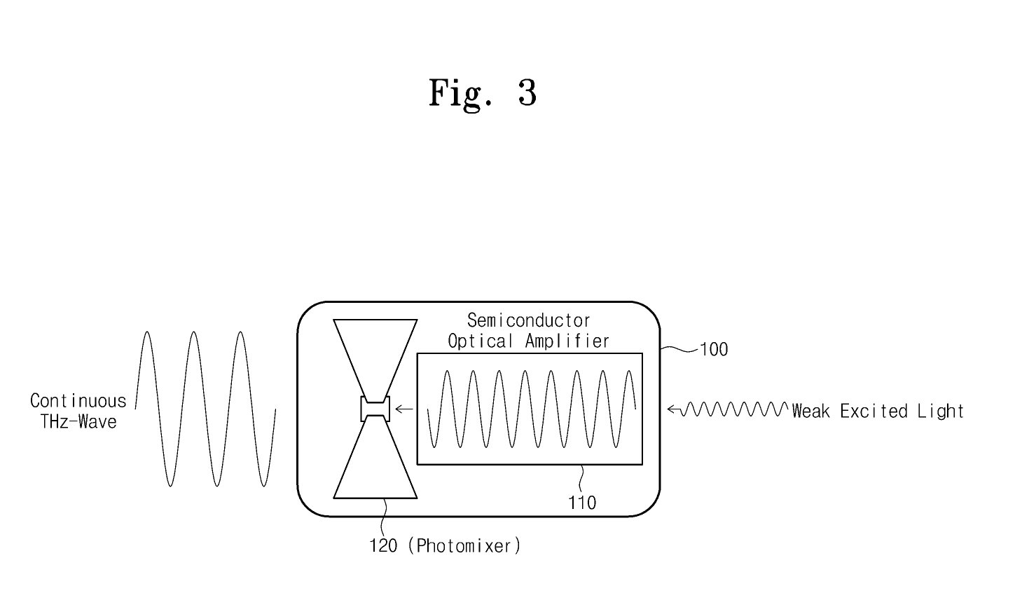

FIG. 3 is a schematic view illustrating a method for generating a continuous terahertz wave (Cw THz-Wave) using the photomixer module of FIG. 1 according to an embodiment.

When the weak excited light formed by beating signals having different wavelengths is incident on the semiconductor optical amplifier integration type photomixer module 100, the weak excited light is first amplified by the semiconductor optical amplifier 110. The excited light amplified in the gain waveguide of the semiconductor optical amplifier 110 is incident on the photomixer 120. Then, the continuous terahertz wave is generated by the excited light incident on a switch portion of the photomixer 120. The intensity of the continuous terahertz wave (CW THz-Wave) may be controlled by the gain of the optical amplifier 110.

The gain of the semiconductor optical amplifier 110 for optimizing the intensity of the terahertz wave generated may be varied depending on the use of the continuous terahertz wave generated.

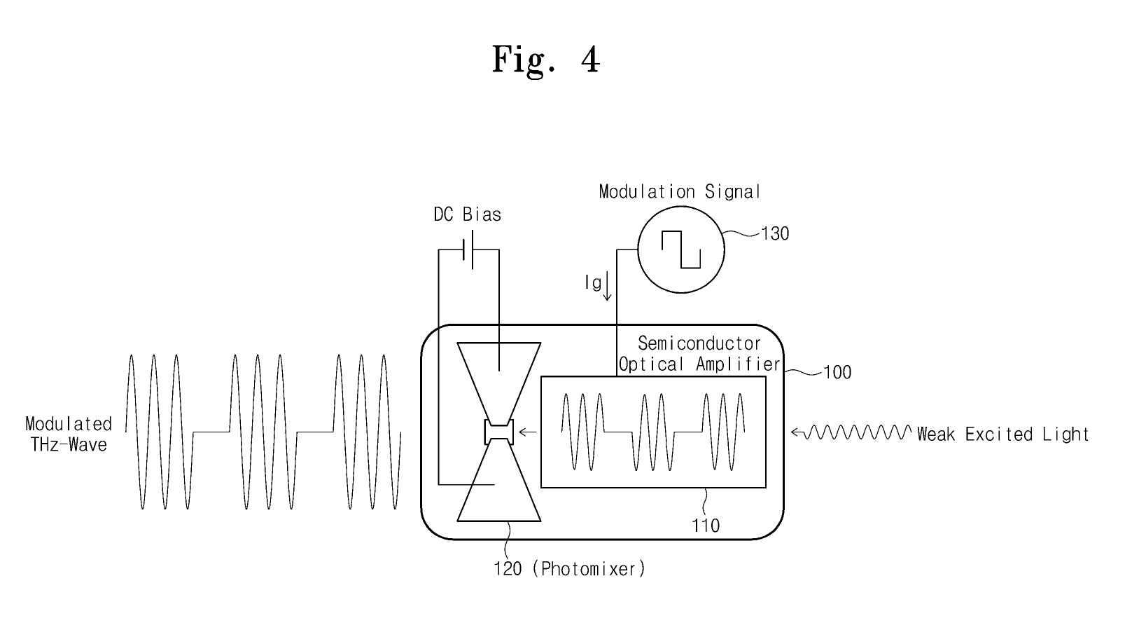

FIG. 4 is a schematic view illustrating a method for generating a modulated terahertz wave using the photomixer module of FIG. 1 according to an embodiment.

In order to use the terahertz wave for the detection of a specific object or the location area communication, reliable receive sensitivity for a specific frequency must be ensured for the detection and receiving. In this case, the method for modulating the bias voltage applied to the photomixer 120 may have a limitation in providing the stability due to the previously described reasons. That is, when the bias voltage of the photomixer 120 to which high voltage is applied is modulated, the stability of the photomixer may be deteriorated and the frequency of the terahertz wave generated when the excited light is directly modulated may become unstable. Accordingly, the gain of the semiconductor optical amplifier 110 may be modulated in a state where direct voltage is applied to the photomixer 120 as the bias voltage.

The following will briefly describe the operation. The weak excited light formed by beating signals having different wavelengths is incident on the photomixer module 100. Then, the incident excited light is amplified by the gain provided from the optical waveguide 112 of the semiconductor optical amplifier 110. At this same time, the gain of the semiconductor optical amplifier 110 may be controlled by a modulation signal 130. When gain current corresponding to the modulation signal 130 is applied to the semiconductor optical amplifier 110, the gain of the gain waveguide of the semiconductor optical amplifier 110 is varied depending on the modulation signal 130. If the modulation signal 130 having a square wave is input, the output excited light of the semiconductor optical amplifier 110 is amplified. In addition, an envelope curve of the amplified excited light may correspond to the modulation signal 130 having the square wave.

The amplified/modulated excited light is incident on the photomixer 120. The modulated terahertz wave is generated and radiated by the excited light incident on the switch portion of the photomixer 120. Fixed direct voltage is provided for the bias of the photomixer 120. Therefore, the frequency unstable problem of the terahertz wave, which is caused by the bias variation of the antennas, can be solved.

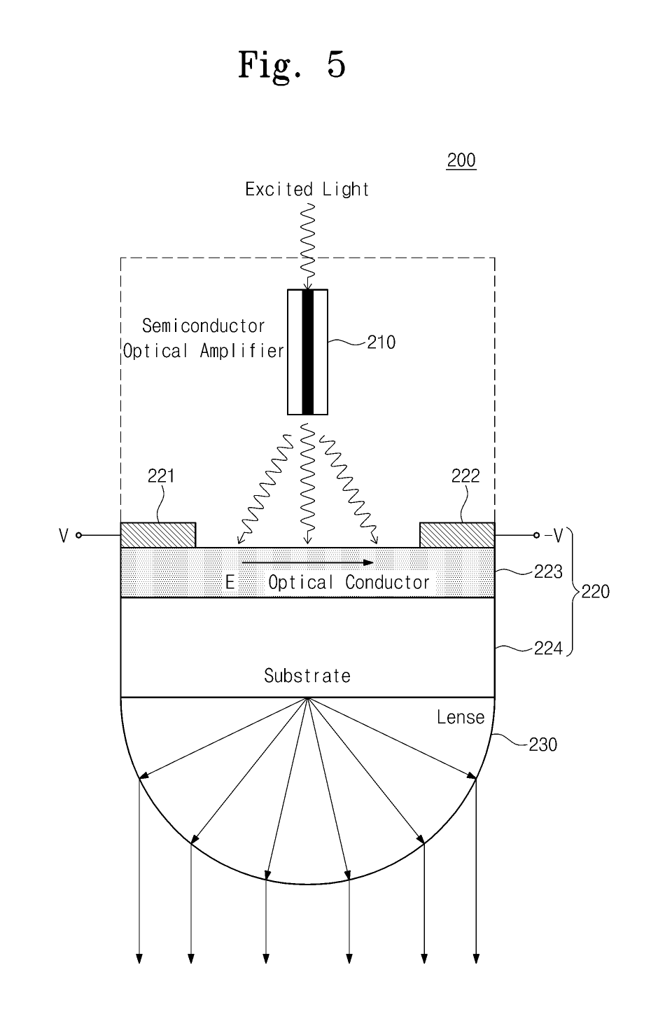

FIG. 5 is a view of a photomixer module according to another embodiment. Referring to FIG. 5, a photomixer module 200 includes a semiconductor optical amplifier 210, a photomixer 220, and a lens 230.

Unlike the foregoing embodiment where the semiconductor optical amplifier and the photomixer are formed on a signal semiconductor substrate, the semiconductor optical amplifier 210 and the photomixer 220 are formed on respective different substrates. That is, the semiconductor optical amplifier 210 and the photomixer 220 are formed as individual devices formed on the respective substrates. The individual devices may be assembled as the photomixer module 200 through a packaging process. The weak excited light formed by two mixed lights having different wavelengths may be amplified or modulated by the semiconductor optical amplifier 210. In addition, the amplified or modulated excited light is incident on the photomixer 220 (shown as a sectional structure) to generate the terahertz wave.

The photomixer 220 may include an optical conductor 223 on a semiconductor substrate 224 or a high response speed photodiode and antennas 221 and 222 formed of metal conductors. The terahertz wave generated by the amplified excited light is mostly radiated to a lower portion of the substrate. A convex lens for adjusting a focal point may be coupled to a lower portion of the substrate to provide directivity for the terahertz wave radiated.

According to the photomixer module 200 of this embodiment, the excited light amplified by the semiconductor optical amplifier 210 may be normally incident on the switch portion of the photomixer 220.

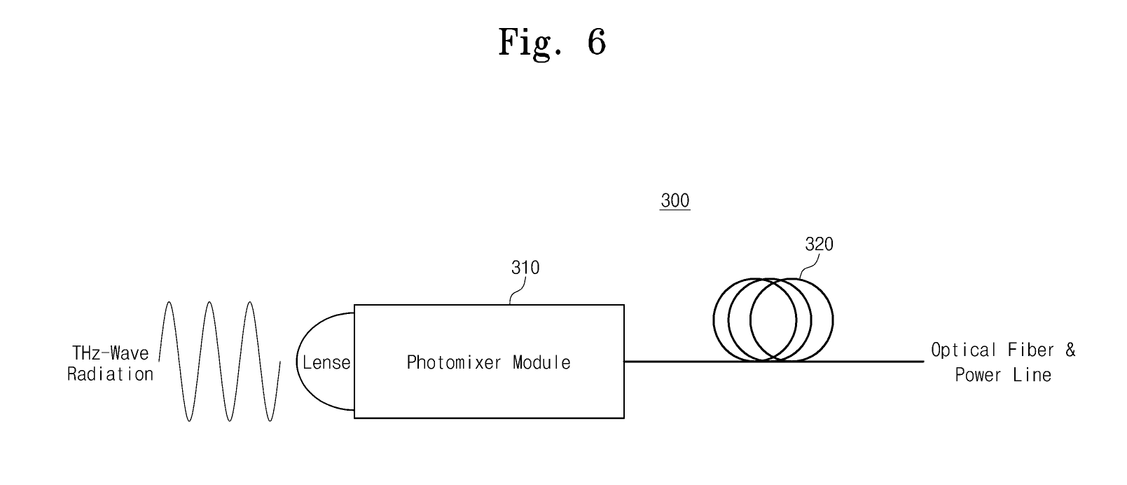

FIG. 6 is a view of a terahertz wave generator having the above-described photomixer module according to an embodiment. Referring to FIG. 6, a terahertz wave generator 300 includes a semiconductor optical amplifier integration type photomixer module 310 having a lens for focusing the terahertz wave radiated and for forming collimated light and a power line and optical fiber 320 for providing driving power and excited light for the semiconductor optical amplifier integration type photomixer 310.

The photomixer module 310 of the terahertz wave 300 may include the semiconductor optical amplifier and the photomixer that are integrated on a single chip. Alternatively, the photomixer module 310 of the terahertz wave 300 may include the semiconductor optical amplifier and the photomixer that are formed on individual chips and packaged as a module.

According to the above-described structure, since the terahertz wave generator includes the semiconductor optical amplifier integration type photomixer module that is small but capable of generating the terahertz wave, the terahertz wave generator or terahertz wave detector can be manufactured to be portable.

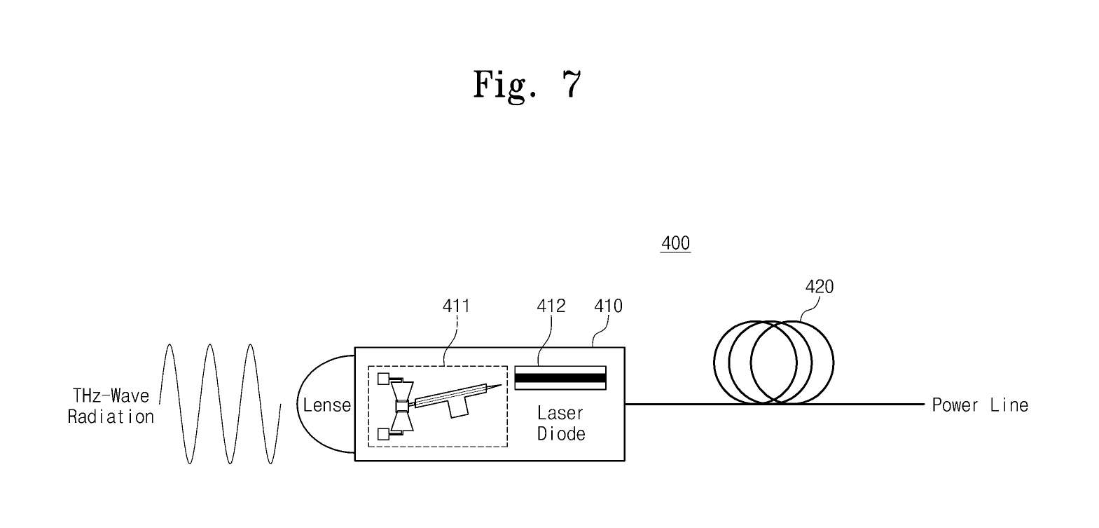

FIG. 7 is a view of a terahertz wave generator having the above-described photomixer module according to another embodiment. Referring to FIG. 7, a terahertz wave generator 400 includes a photomixer module 410 and a power line 420 for providing electric power for the photomixer 410. The photomixer module 410 includes an optical amplifier integration photomixer 411 and a laser diode 412.

The photomixer of the photomixer module 410 is integrated with a semiconductor optical amplifier on a signal semiconductor substrate.

The laser diode 412 may be a dual wavelength semiconductor laser diode that can beat and output laser lights having different wavelengths. In this case, since the laser lights having different wavelengths are output from the laser diode 412 and one of the laser lights can be continuously tuned, the portability can be enhanced.

Alternatively, the laser diode 412 may be a laser diode having two outputs, one of which has a fixed wavelength and the other of which is varied depending on discrete tuning such as mode hopping.

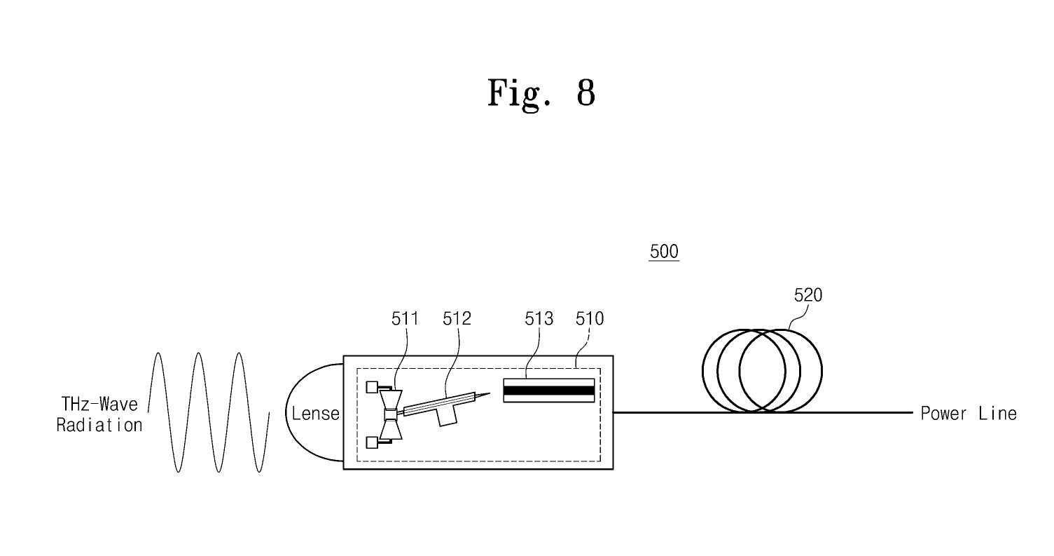

FIG. 8 is a view of a terahertz wave generator having the above-described photomixer module according to another embodiment. Referring to FIG. 8, a terahertz wave generator 500 includes a photomixer module 510 and a power line 520 for providing electric power for the photomixer module 510. The photomixer module 510 of this embodiment includes a photomixer 511, a semiconductor optical amplifier 512, and a dual wavelength semiconductor laser diode 513, which are integrated on a single chip. Alternatively, the photomixer module 510 may include an optical conductor antenna 511, a semiconductor optical amplifier 512, and a dual wavelength semiconductor laser diode 513, which are formed in respective individual modules.

As described with reference to FIGS. 6 to 8, each of the terahertz wave generators 300, 400, and 500 includes the power line. However, the present invention is not limited to this. The terahertz wave generators may include a built-in power such as a battery.

According to the embodiments, a photomixer module that can be integrated and generate a terahertz wave having a stable frequency can be realized. In addition, since a small, reliable photomixer module can be formed, a terahertz wave generator/detector that is highly portable can be provided.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A photomixer module comprising:
a semiconductor optical amplifier amplifying incident laser light; and
a photomixer that is formed as a single module together with the semiconductor optical amplifier and excited by the amplified laser light to generate a continuous terahertz wave.

2. The photomixer module of claim 1, wherein the semiconductor amplifier and the photomixer are formed on as a single chip.

3. The photomixer module of claim 1, wherein the semiconductor optical amplifier and the photomixer are formed as individual chips and optically coupled to each other in a single package.

4. The photomixer module of claim 3, wherein the amplified laser light is normally incident on a surface of an optical conductor of the photomixer.

5. The photomixer module of claim 1, wherein the incident laser light is generated by beating laser lights having different wavelengths.

6. The photomixer module of claim 1, wherein the semiconductor optical amplifier modulates the incident laser light depending on a modulation signal

7. The photomixer module of claim 1, further comprising a laser diode for generating the incident laser light.

8. The photomixer module of claim 7, wherein the laser diode comprises a dual wavelength semiconductor laser diode generating laser lights having different wavelengths.

9. The photomixer module of claim 8, wherein the laser diode is formed on a single substrate on which the semiconductor optical amplifier and the photomixer are formed.

10. A method of generating a terahertz wave, comprising:
generating excited light by beating laser lights having different wavelengths;
amplifying the excited light using a semiconductor optical amplifier; and
generating the terahertz wave by allowing the amplified excited light to be incident on the photomixer,
wherein the semiconductor optical amplifier and the photomixer are formed as a single module.

11. The method of claim 10, wherein the excited light is generated by a semiconductor laser diode.

12. The method of claim 11, wherein the semiconductor laser diode is a dual wavelength semiconductor laser diode generating semiconductor laser lights having different wavelengths.

13. The method of claim 10, further comprising, after the amplifying of the excited light, modulating the amplified excited light.

14. The method of claim 10, wherein the photomixer is biased as direct voltage of a fixed level.
